(19) United States
(12) Patent Application Publication
(10) Pub. No.: US 2007/0279139 A1
(43) Pub. Date: Dec. 6, 2007

(54) Integrated differential oscillator circuit

(76) Inventors: Samir El Rai, Duisburg (DE); Ralf Tempel, Duisburg (DE)

Correspondence Address: MCGRATH, GEISSLER, OLDS & RICHARDSON, PLLC, P.O. BOX 1364, FAIRFAX, VA, 22038-1364, US

(21) Appl. No.: 11/783,829

(22) Filed: Apr. 12, 2007

(30) Foreign Application Priority Data
Apr. 12, 2006 (DE) DE102006017188

(51) Int. Cl. H03B 5/12; H03B 5/24

(52) U.S. Cl. 331/117 R; 331/108 R

(57) ABSTRACT

An integrated differential oscillator circuit is provided, which has an amplifier circuit with an input and an output, a frequency-selective feedback network with a first inductor and a second inductor, and a DC power supply. The oscillator circuit is distinguished in that the output is transformer-coupled to the input through the first inductor and the second inductor of the feedback network, wherein the output is connected to a first DC voltage through the first inductor and a first DC path, and the input is connected to a second DC voltage of the DC power supply through the second inductor and a second DC path.

This nonprovisional application claims priority under 35 U.S.C. § 119(a) on German Patent Application No. DE 102006017188, which was filed in Germany on Apr. 12, 2006, and which is herein incorporated by reference.

### BACKGROUND OF THE INVENTION

1. Field of the Invention

The present invention relates to an integrated differential oscillator circuit which has an amplifier circuit with an input and an output, and has a frequency-selective feedback network with a first inductor and a DC power supply.

2. Description of the Background Art

An oscillator circuit is known from WO 99/43079, which corresponds to U.S. Pat. No. 6,002,303. This document shows a differential oscillator design with two resonant circuits that are deattenuated through an amplifier circuit of two transistors in common-base configuration. In the terminology of WO 99/43079, the first resonant circuit has a first resonant element, a first feedback path, and a differential coupling element. Various embodiments are specified, which result from different combinations of resistive, capacitive, magnetic and inductive embodiments of the components.

In one embodiment, which appears to illustrate an inductive feedback, the first resonant element has a resistive character, the feedback path has an inductive character, and the differential coupling element has a capacitive character. In the drawings, the feedback path is parallel to the collector-emitter path of one of the two transistors and is closed through an inductive component, which would mean a DC short circuit of the collector-emitter path in an embodiment of the inductive component as a coil.

In three other embodiments, capacitive feedback paths are specified. The differential coupling element lies between nodes to which are connected the emitters of the transistors, the feedback paths, and, in each case, one bias element that connects one of the nodes to a ground. This ground obviously represents a DC ground, since WO 99/43079 expressly distinguishes this ground from a “virtual ground point,” which is to say from AC ground. Current sources or current sinks are disclosed as bias elements. The terminals of the current sources/current sinks connected to the transistors are separated from one another only by the differential coupling element. A separate bias element in the form of a current source or current sink is thus required in each case in order to prevent an AC short circuit of the differential coupling element.

Such oscillators are also called feedback oscillators because of the feedback path. Also known are so-called reflection oscillators, for example from the publication “Optimizing MMIC Reflection-Type Oscillators,” 2004 IEEE MTT-S Digest, pp. 1341 ff. According to this document, such an oscillator has an active component that is connected to an AC ground through three impedances. In this context, two terminals are connected to ground in such a manner that a negative impedance is produced at the third terminal. A third impedance is connected to the AC ground there in order to set the resonant frequency.

As already described in WO 99/43079, when designing an oscillator it is always necessary to make compromises between requirements, one of which often can only be satisfied at the expense of another. A list of such requirements—which is not exhaustive—includes, for example, manufacturability in large quantities at the lowest possible costs, small space requirements for the oscillator circuit, low power consumption, a high signal-to-noise ratio, and low sensitivity to production-related variations in the circuit characteristics.

### SUMMARY OF THE INVENTION

It is therefore an object of the present invention to provide an integrated differential oscillator circuit with an improved signal-to-noise ratio, a relatively wide tuning range and/or a relatively high quality, a relatively high efficiency and relatively small effects from production-related variations on the circuit characteristics.

This object is attained by an oscillator circuit of the aforementioned type in that the output is transformer-coupled to the input through a first inductor and a second inductor of the feedback network, wherein the output is connected to a first DC voltage through the first inductor and a first DC path, and the input is connected to a second DC voltage of the DC power supply through the second inductor and a second DC path.

As a result of the connection of the second inductor to the second DC reference voltage, the DC path required for deattenuating the resonant circuit and establishing the operating point of the amplifier circuit is routed through the second inductance to the amplifier circuit. As a general rule, inductors are implemented by metallic means, and have a negligibly small ohmic resistance as compared to bias elements of semiconductor material.

At such small ohmic resistance values, small differences in the resistance values, such as can arise from process variations in the production of integrated oscillator circuits, play only a secondary role. By contrast, in the customary DC connection of the amplifier circuit with the aid of resistors of semiconductor material or with the aid of active current sources or current sinks that contain transistors, process variations result in relatively large dispersions in the resistance values.

Moreover, the noise voltages u_r arising in the connecting lines are directly proportional to the value R of their resistances (u_r²=4k_{B}TR, where k_{B}=Boltzmann's constant and T=absolute temperature).

Because of the small resistance values of the inductors, the invention provides a low-noise DC connection of the amplifier circuit with a reduced range of effects due to process variations. This advantage is of great importance precisely because of the differential signal processing: Differential signal processing requires the best possible symmetry in the DC supply of the amplifier circuit. Deviations in the symmetry can lead to differences in the DC voltage at terminals of the differential input of the amplifier circuit. In the aforementioned prior art, such voltage differences can arise as a result of manufacturing-related variation of the properties of the two current sources, and can lead to different operating points of the transistors serving as amplifiers there. These transistors then are no longer driven in a precisely differential manner, producing adverse effects on the quality of the signal-to-noise ratio of the output signal of the oscillator circuit.

In contrast, as a result of the inventive connection of the input of the amplifier circuit to the second DC voltage of the DC power supply through the second inductor and the second DC path, a very low resistance of the DC power supply is achieved overall. Because of the differential design, separate DC path sections to the terminals of the differential input are still necessary. However, these sections are implemented through the extremely low resistance inductors. The total resistance of the DC power supply is thus dominated at the input side of the amplifier arrangement by components such as resistors or transistors of a current source of the DC power supply, which components are arranged in a circuit section that is common to both terminals of the differential input. As a result of these influences, asymmetries in the DC power supply of the amplifier circuit are avoided almost completely.

The transformer coupling permits a feedback of AC signals while it blocks DC currents. For configurations of the amplifier circuit with transistors, it thus permits the collector and emitter DC voltages or drain and source DC voltages required for transistor operation, in particular.

Since the tuning range, which is to say the bandwidth over which the resonant frequency can be tuned, is limited with increasing frequency by parasitic capacitances of the resonant circuit and/or the amplifier circuit, a reduction in the parasitic capacitances and thus an increase in the width of the frequency tuning range is produced as an additional great advantage of the transformer coupling. The reduction in parasitic capacitances achieved with the transformer coupling can be used either to achieve a maximum increase in the tuning range for constant quality, or to achieve a maximum increase in the quality for constant tuning range, or to achieve a simultaneous improvement of quality and tuning range to submaximal levels.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 illustrates a block diagram of a conventional art oscillator circuit;

FIG. 2 illustrates a first example embodiment of the invention;

FIG. 3 illustrates a first embodiment of an amplifier circuit with transistors in a common-base configuration;

FIG. 4 illustrates an embodiment of an amplifier circuit with transistors in a common-emitter configuration;

FIG. 5 illustrates embodiments of adjustable capacitors;

FIG. 6 illustrates dependencies of the resonant circuit quality on a tuning range and a size of parasitic capacitances;

FIG. 7 illustrates a possible geometric configuration of the resonant circuit inductors and the arrangement of capacitors;

FIG. 8 illustrates another embodiment with additional capacitors for an optimized impedance matching;

FIG. 9 illustrates an embodiment with additional capacitors distributed over the length of the inductors;

FIG. 10 illustrates an embodiment with overlapping conductor loops in various levels; and

FIG. 11 illustrates a cross-section through the subject of FIG. 10.

### DETAILED DESCRIPTION

In this connection, like elements are labeled with like reference symbols in all figures. Specifically, FIG. 1 shows the known principle of a feedback oscillator circuit 10, which circuit in general has an amplifier circuit 12 with a frequency-selective feedback network 14. The amplifier circuit amplifies an input signal U1 into an output signal U2=A*U1. The feedback network 14 selects a resonant frequency from the output signal U2 and feeds the output signal of the selected frequency back to the input in attenuated form as the signal U3=k*U2. As is known, a stable oscillation of the output signal U2 is established when the amplitude of the feedback signal U3 is equal to the amplitude of the input signal U1. If the product of the gain A and attenuation k is defined as the loop gain g, then g must be equal to 1. Moreover, the phase shift between U1 and U3 must permit a constructive interference, and thus in the ideal case must be an integer multiple of 2π. These relationships are entirely general in their application and are known (see, for example, “Halbleiterschaltungstechnik” by Tietze Schenk, 9^{th} edition, pages 458, 459). The feedback network can be divided still further into a first part 14.a, which selects the frequency, and a second part 14.b, which feeds the selected signal back to the input.

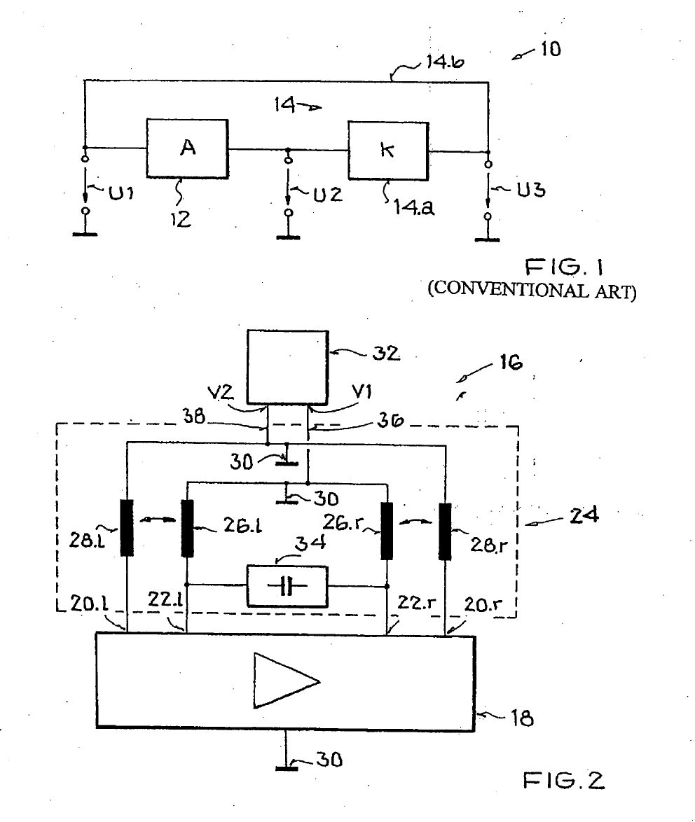

FIG. 2 shows a first exemplary embodiment of the invention with an integrated oscillator circuit 16, which works with differential signals. The integrated oscillator circuit 16 has an amplifier circuit 18 with a differential input 20.l, 20.r and with a differential output 22.l, 22.r, and also has a frequency-selective feedback network 24 with a first inductor 26.l, 26.r and with a second inductor 28.l, 28.r and a DC power supply 32. In addition to the inductors 26.l, 26.r and 28.l, 28.r, the frequency-selective feedback network 24 has at least one capacitor 34. Together with the first inductor 26.l, 26.r, the capacitor 34 forms a parallel resonant circuit, which is located between the differential output 22.l, 22.r of the amplifier circuit 18 and the DC power supply 32. The frequency selectivity results from the fact that the parallel resonant circuit has a low impedance outside its resonant frequency, which drains off signals with corresponding frequencies through the DC power supply. Only within the resonant bandwidth is the impedance large enough to feed a signal into the actual feedback.

The oscillator circuit 16 shown in FIG. 2, like the other oscillator circuits that are presented, is implemented as an integrated circuit on a semiconductor substrate in a conventional semiconductor manufacturing process. In this regard, the inductors are preferably formed by structured trace sections in metallization levels. The capacitors are, for example, formed with a thin oxide layer as dielectric, which lies on a highly-doped layer of semiconductor material and is covered by a metal layer (MIS=metal insulator semiconductor structure). MIM (metal insulator metal) structures also come into consideration.

The differential output 22.l, 22.r is transformer-coupled (magnetically) to the input 20.l, 20.r through the first inductor 26.l, 26.r and the second inductor 28.l, 28.r of the feedback network 24. In this regard, the output 22.l, 22.r is connected to a first DC voltage V1 of the DC power supply 32 through the first inductor 26.l, 26.r and a first DC path 36. The input 20.l, 20.r is connected to a second DC voltage V2 of the DC power supply 32 through the second inductor 28.l, 28.r and a second DC path 38.

FIG. 2 thus shows an oscillator circuit 16 with a purely transformer-coupled feedback. In this regard, the first inductor 26.l, 26.r and the second inductor 28.l, 28.r are each divided into a left inductor section 26.l, 28.l and a right inductor section 26.r, 28.r. The left inductor sections 26.l, 28.l and the right inductor sections 26.r, 28.r are located adjacent to one another in pairs in order to achieve transformer coupling. This coupling is illustrated in FIG. 2 by arrows. The coupling takes place in that the magnetic field of one inductor passes through the other inductor, and vice versa. The transformer coupling has the advantage of simplified circuit design (fewer components) and galvanic isolation. Further advantages result in connection with a tunable resonant circuit capacitor 34, and are discussed below.

The DC path 36 for the connection to the first DC voltage V1 is preferably connected to a center tap of the first inductor 26.l, 26.r. Similarly, the DC path 38 for the connection to the second DC voltage V2 is preferably connected to a center tap of the second inductor 28.l, 28.r. Because of the symmetry of the arrangement, each center tap then constitutes an AC ground 30 at which no AC component arises.

In this way, all voltages required for the operation of the oscillator circuit 16 can be supplied externally by existing components such as the inductors 26.l, 26.r, 28.l, 28.r, which themselves are connected to AC voltages that are in a sense static, which is to say to AC grounds 30 having different DC voltages.

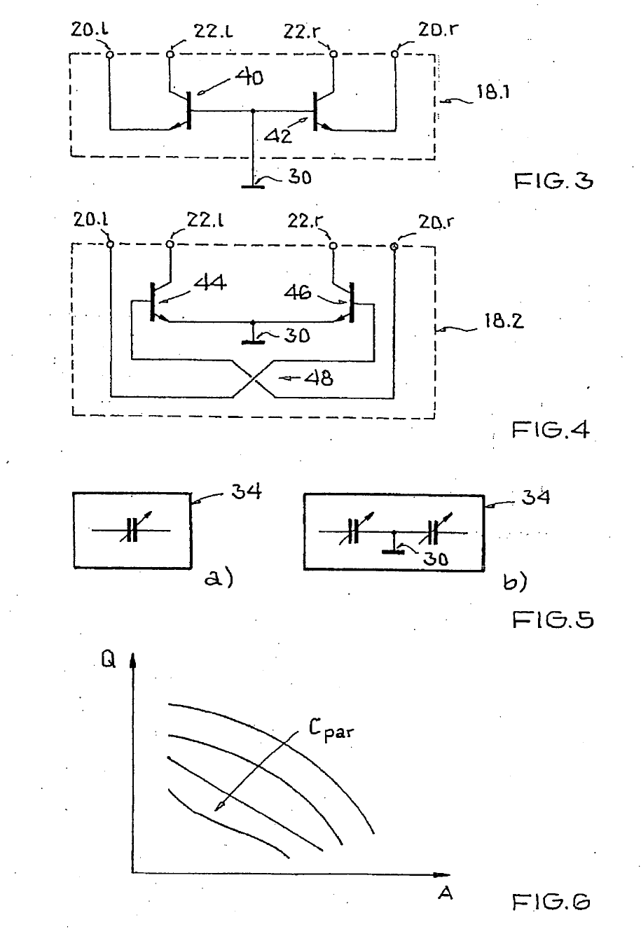

FIG. 3 shows a first embodiment 18.1 of an amplifier circuit 18, such as can be used in FIG. 2. In the embodiment 18.1, the amplifier circuit 18 has two bipolar transistors 40, 42 in a common-base configuration, whose bases are connected together, wherein the connection of the two bases in this circuit forms an AC ground 30. The collector of the transistor 40 constitutes the output 22.l of the amplifier circuit 18.1, and the collector of the transistor 42 constitutes its output 22.r. Similarly, the emitter of the first transistor 40 constitutes the input 20.l of the amplifier circuit, and the emitter of the second transistor 42 constitutes its input 20.r.

When the embodiment 18.1 is used as an amplifier circuit 18 in FIG. 2, each output 20.l (20.r) is connected to an output 22.l (22.r) through the feedback network 24, where the connection takes place by means of a transformer coupling of the left inductors 28.l, 26.l (right inductors 28.r, 26.r). The transformer coupling permits the feedback of AC signals while blocking DC. It thus, in particular, permits the collector/emitter DC voltages necessary for transistor operation.

A signal at the collector of one of the two transistors 40, 42 is fed back to the emitter of the same transistor 40, 42 through the associated transformer coupling, by which means the transistor 40, 42 is modulated at its emitter. With such modulation, the signal at the collector as the output of the amplifier circuit 18 follows the input signal at the emitter with like phase. The phase condition for oscillation is met to this extent.

As an alternative to the embodiment 18.1 in FIG. 3, the amplifier circuit 18 can also have two bipolar transistors 44, 46 in common-emitter configuration, as is shown in FIG. 4 as embodiment 18.2. In this case, the emitters of the two transistors 44, 46 are connected together, forming at one point of the connection an AC ground 30 at which the AC components of the two emitter voltages cancel out.

In this embodiment, the input 20.l (20.r) of the amplifier circuit 18.2 is connected to the base of the transistor 46 (44), while the output 22.l (22.r) is connected to the collector of the transistor 44 (46). In an application of the embodiment 18.2 as an amplifier circuit 18 from FIG. 2, each input 20.l (20.r) is connected to an output 22.l (22.r) by feedback with transformer coupling through the left inductors 28.l, 26.l (right inductors 26.r, 28.r). Here, too, the transformer coupling permits the feedback of AC signals while blocking DC, thus, in particular, permitting the collector and emitter DC voltages necessary for transistor operation.

With modulation of a transistor by an input signal at its base, the output signal at the collector of the same transistor always follows the input signal with a phase shift of π. Since the parallel resonant circuit having the first inductor 26.l 26.r and the capacitor lies between the collectors of the two transistors 44 and 46, and since an AC voltage arises across the parallel resonant circuit in the operation of the oscillator circuit 16, the parallel resonant circuit creates an additional phase shift of π between the two connected collectors. Thus, a phase shift of π arises at the collector of the transistor 44 relative to the collector of the transistor 46. Depending on the sign of the phase shift, the total phase shift between the base of the transistor 46 and the collector of the transistor 44 is thus either equal to 0 or equal to 2π. As a result of the cross-coupling 48, wherein the base of the left (right) transistor 44 (46) is connected to the right input 20.r (left input 20.l), the signal propagating from the collector of the transistor 44 to the base of the transistor 46 arrives there with an overall phase shift of zero or 2π relative to the input signal. The converse also applies, so that the phase prerequisite for oscillation is also met to this extent with the common-emitter configuration of the embodiment 18.2.

FIGS. 3 and 4 show, in each case, embodiments with a transformer coupling between an input 20.l, 20.r and an output 22.l, 22.r of an embodiment 18.1, 18.2 of a differential amplifier circuit 18. Starting from the common-emitter configuration, interchanging the emitters and collectors of the two transistors 44, 46 while matching the polarity of the DC power supply 32 results in another embodiment of an amplifier circuit with two bipolar transistors in a common-collector configuration.

Although the above-described embodiments 18.1, 18.2 of amplifier circuits 18 have been discussed using bipolar NPN transistors 40, 42, 44, 46, it is understood that corresponding embodiments can also be built with bipolar PNP transistors or with unipolar transistors of the n-channel or p-channel type. In the embodiments with unipolar transistors, such transistors are used in (unipolar) common-gate, common-source or common-drain configurations analogous to the (bipolar) common-base, common-emitter or common-collector configuration.

In another embodiment, the values of the capacitor 34 in FIG. 2 are adjustable in continuous and/or in stepwise fashion. Examples of known continuously adjustable capacitive components are varactor, variable-capacitance, Schottky, MOS and MEM diodes. Examples of capacitive elements with discretely adjustable capacitance value are so-called CDAC circuits (CDAC=capacitor digital-to-analog converter, see for example US 2005/0083221), switched MIM capacitors (MIM=metal insulator metal), and switched PolyCaps. The important factor in each case is that the capacitors can be integrated into integrated circuits, which is true of the cited embodiments.

The adjustable capacitor 34 is shown schematically in FIG. 5. FIG. 5a shows an embodiment of the first capacitor 34 with a single adjustable capacitive component. FIG. 5b shows an embodiment of the capacitor 34 with two adjustable capacitive elements between which an AC ground 30 is formed.

With the adjustable capacitor 34, the oscillator circuit 16 constitutes, for example, a voltage-controlled oscillator VCO 16. For technical reasons, almost exclusively capacitive components 34 are used as drivable control components for frequency tuning in a VCO 16. In this context, the tuning range, which is to say the bandwidth over which the resonant frequency can be tuned, is limited with increasing frequency by parasitic capacitances of the resonant circuit and/or the amplifier circuit 18. This yields another great advantage of transformer coupling over the capacitive couplings otherwise used. With regard to the width of the frequency tuning range, the capacitive couplings count among the problematic parasitic capacitances.

The tuning range is proportional to the square root of the quotient of the difference of the maximum and minimum resonant circuit capacitances in the numerator, and the sum of the maximum and minimum resonant circuit capacitances in the denominator. In this regard, the value of the resonant circuit capacitance is comprised of the tunable and parasitic components or capacitances. In contrast to a capacitive coupling, the transformer coupling results in smaller values of the parasitic capacitances, since the coupling capacitances can be eliminated. As a rule, the values of the coupling capacitances are greater than the value of the tunable component 34 of the resonant circuit capacitance. Since the parasitic capacitances always drop out of the difference in the numerator, the width of the tuning range increases with decreasing parasitic capacitance values. Since the parasitic capacitance value is small with transformer coupling, the denominator is correspondingly small for transformer coupling, resulting in a correspondingly larger tuning range.

In addition, the quality factor Q of the resonant circuit depends on the quotient of the maximum capacitance in the numerator and the minimum capacitance in the denominator. The value of the quality factor drops with increasing quotient, first gradually and then more steeply. The steeply dropping quality factor thus limits the maximum tuning range.

As the size of the parasitic capacitances decreases, the quotient itself increases monotonically from a limit value of 1 to a value of the quotient that is determined only by the minimum and maximum values of the tunable capacitance component. The smaller the parasitic capacitances become, the larger the quotient becomes.

If one plots the quality factor Q as a function of the tuning range A, the qualitative result is the family of curves shown in FIG. 6 with the value Cpar of the parasitic capacitances as a parameter. The lower curves belong to larger values of Cpar. The reduction of Cpar achieved by transformer coupling can thus be used either to achieve maximum increase in the tuning range for constant quality, or to achieve a maximum increase in the quality for constant tuning range, or to achieve a simultaneous improvement of quality and tuning range to submaximal levels.

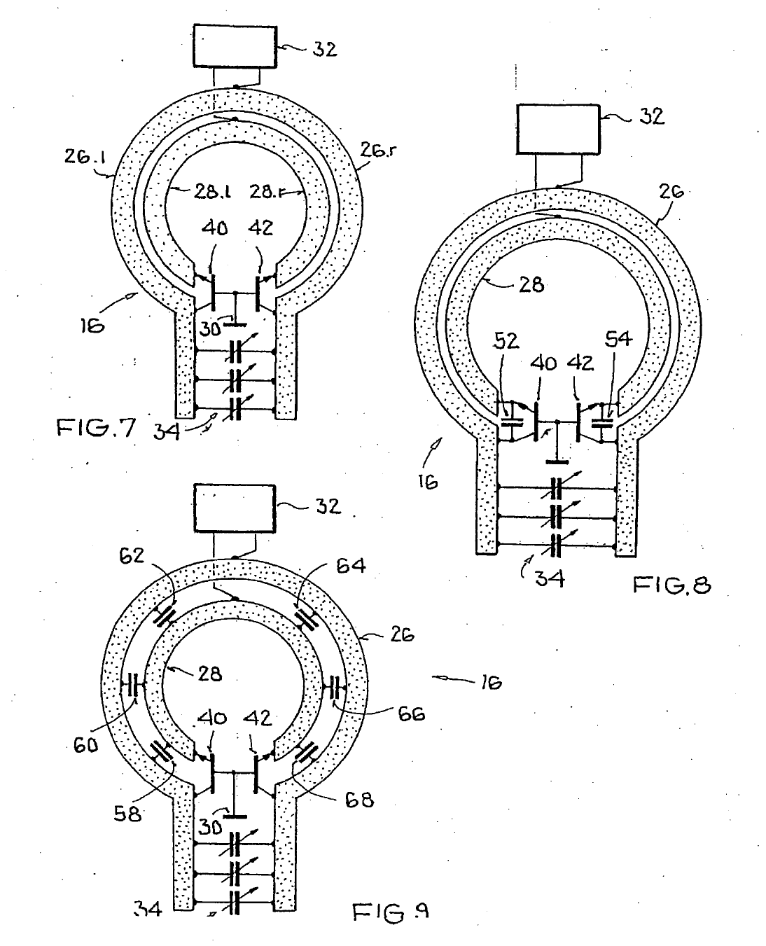

FIG. 7 shows one possible layout of an integrated oscillator circuit 16 with largely circular, concentric resonant circuit inductors 28, 26. In each case, each resonant circuit inductor 28, 26 has at least one turn or transmission line. The inductors 28, 26 are each divided into left inductors 28.l, 26.l and right inductors 28.r, 26.r by a center tap to which the DC power supply 32 is connected. FIG. 7 represents, among other things, an embodiment of the oscillator circuit 16 in which the first inductor 26 and the second inductor 28 each have at least one conductor loop, wherein both conductor loops lie in a plane of the integrated circuit 16 and one of the conductor loops runs in a region of the plane surrounded by the other conductor loop.

The conductor loops can be nearly circular, elliptical, or rectangular. In place of a pure rectangular, circular, or elliptical shape, other embodiments can also have conductor loops with piecewise straight segments in regular or irregular and convex or concave polygonal shapes and/or conductor loops with piecewise curved convex or concave segments or composite shapes composed of curved and straight segments.

In another embodiment, the frequency-selective network 24 composed of the resonant circuit inductors and capacitors has an additional capacitive coupling between the first inductor 26 and the second inductor 28, as is shown schematically in FIGS. 8 through 11. The additional capacitive coupling permits optimization of the input and/or output impedance of the transistors operating as amplifiers. In the embodiment in FIG. 8, additional capacitors 52, 54 are located between the collectors and emitters of the transistors 40, 42 in common-base configuration. This permits an optimized impedance matching of amplifier circuit and feedback network. The optimized impedance matching then yields maximum power gain (efficiency) and noise matching and thus a maximum signal-to-noise ratio as well.

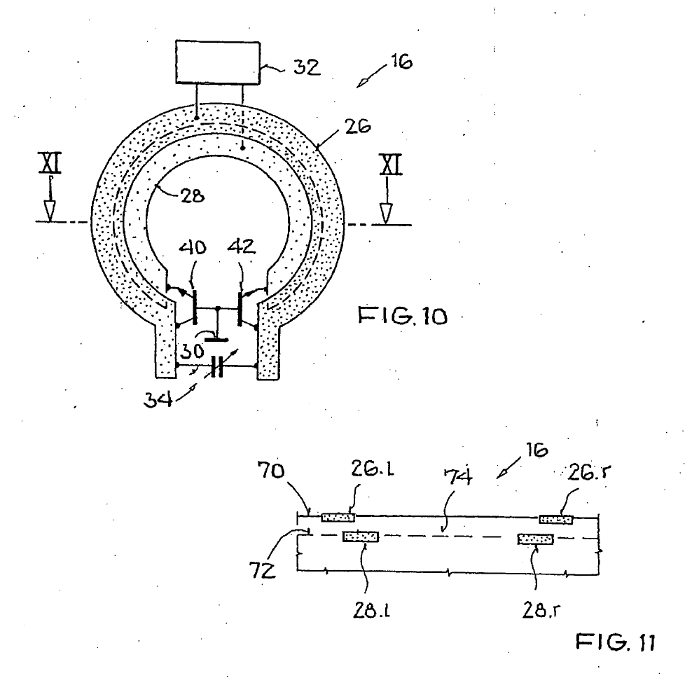

In the additional embodiment in FIG. 9, a fairly large number of additional capacitors 58, 60, . . . , 68 are distributed along the length of the inductors 26, 28. FIG. 10 and the cross-section in FIG. 11 show an embodiment in which an additional capacitance distributed over the length of the inductors 26, 28 is produced by an overlapping of the inductors 26, 28 in different levels 70, 72 of a semiconductor substrate 74 of an integrated oscillator circuit 16, so that the first inductance 26 and the second inductance 28 are arranged to completely or partially overlap one another.

With the exception of the abstract embodiment in FIG. 1, all oscillator circuits described above have transformer-coupled feedback. They can thus be categorized as being of the feedback oscillator type. However, the invention is not limited to use in feedback oscillators, but can also be used in reflection oscillators. A reflection oscillator results, for example, from a variation of the amplifier circuit 18.1 from FIG. 3 wherein the bases of the two transistors 40, 42 are [not] connected to one another directly, but instead through an impedance of, e.g., two series-connected LC networks, and wherein the connection point between the LC networks forms an AC ground. In this way the circuit principle of a reflection oscillator is realized in differential form: Each of the three terminals of each of the two transistors 42, 50 is connected to an AC ground through an impedance, wherein a negative resistance results at each emitter, by means of which the associated resonant circuit is deattenuated.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. An integrated differential oscillator circuit comprising:
an amplifier circuit having an input and an output;
a frequency-selective feedback network having a first inductor and a second inductor; and
a DC power supply,
wherein the output is transformer-coupled to the input through the first inductor and the second inductor of the feedback network,
wherein the output is connected to a first DC voltage through the first inductor and a first DC path, and
wherein the input is connected to a second DC voltage of the DC power supply through the second inductor and a second DC path.

2. The oscillator circuit according to claim 1, wherein the first DC path and the second DC path each form an AC ground.

3. The oscillator circuit according to claim 1, wherein the first DC path and the second DC path are each operatively connected to a reference voltage terminal through a capacitor.

4. The oscillator circuit according to claim 1, further comprising an amplifier circuit that has at least one bipolar transistor in a common-base configuration, common emitter configuration, or common-collector configuration.

5. The oscillator circuit according to claim 1, further comprising an amplifier circuit that has at least one unipolar transistor in a common-gate, common-source or common-drain configuration.

6. The oscillator circuit according to claim 1, wherein the frequency-selective feedback network has a tunable capacitor that forms a parallel resonant circuit together with the first inductor.

7. The oscillator circuit according to claim 6, wherein the tunable capacitor is continuously adjustable or stepwise adjustable.

8. The oscillator circuit according to one claim 1, further comprising an additional capacitive coupling between the first inductor and the second inductor.

9. The oscillator circuit according to claim 8, further comprising separate capacitors that are located electrically between the first inductor and the second inductor.

10. The oscillator circuit according to claim 1, wherein the first inductor and the second inductor each have at least one conductor loop.

11. The oscillator circuit according to claim 10, wherein both conductor loops lie in a plane of the integrated oscillator circuit, and wherein one of the conductor loops runs in a region of the plane surrounded by the other conductor loop.

12. The oscillator circuit according to claim 10, wherein the two conductor loops lie in different planes of the integrated oscillator circuit.

13. The oscillator circuit according to claim 12, wherein the two conductor loops are arranged such that they completely or partially overlap one another.
